(19) United States
(12) Patent Application Publication
(10) Pub. No.: US 2012/0240007 A1
(43) Pub. Date: Sep. 20, 2012

(54) LDPC DECODING FOR SOLID STATE STORAGE DEVICES

(75) Inventors: Richard D. BARNDT, San Diego, CA (US); Xinde HU, San Diego, CA (US); Anthony D. WEATHERS, San Diego, CA (US)

(73) Assignee: STEC, Inc., Santa Ana, CA (US)

(21) Appl. No.: 13/277,876

(22) Filed: Oct. 20, 2011

Related U.S. Application Data
(60) Provisional application No. 61/405,156, filed on Oct. 20, 2010.

(51) Int. Cl. H03M 13/09; G06F 12/02; G06F 11/08

(52) U.S. Cl. 714/758; 714/E11.03

(57) ABSTRACT

A solid state storage device includes a flash memory and a controller configured to store data in the flash memory via a plurality of channels. The stored data is encoded using a low-density parity-check code. Hard-decision decoders are configured to decode encoded data received from the flash memory via respective channels of the plurality of channels using the low-density parity-check code and to provide decoded data to the controller in response to one or more read commands from the controller. A soft-decision decoder is configured to decode the encoded data received from the flash memory using the low-density parity-check code and to provide the decoded data to the controller in response to one of the plurality of hard-decision decoders failing to decode the encoded data. The encoded data is obtained by the soft-decision decoder using a plurality of read-retry operations.

This application claims the benefit of U.S. Provisional Application No. 61/405,156, entitled LDPC DECODING FOR SOLID STATE DRIVES and filed on Oct. 20, 2010, which is hereby incorporated by reference herein.

### BACKGROUND

Solid state storage devices, such as solid state drives (SSDs), are increasingly popular solutions for both consumer and enterprise data storage needs. As the flash memory used in these storage devices ages, however, bit error rates increase. Error-correcting codes (ECCs) may be used to help overcome bit errors and prolong the useful life of the storage devices. Relatively complex ECCs, such as low-density parity-check (LDPC) codes, may further prolong the useful life of the storage devices. However, the processing required to correct bit errors using complex ECCs may negatively impact the overall performance of a storage device and outweigh the benefits of prolonging the life of the storage device. In high-performance applications, the use of complex ECCs may not be feasible due to the negative impact of error correction operations on overall device performance.

### SUMMARY

According to one aspect of the subject technology, a solid state storage device is described herein. The solid state storage device includes a flash memory and a controller configured to store data in the flash memory via a plurality of channels. The stored data is encoded using a low-density parity-check code. Hard-decision decoders are configured to decode encoded data received from the flash memory via respective channels of the plurality of channels using the low-density parity-check code and to provide decoded data to the controller in response to one or more read commands from the controller. A soft-decision decoder is configured to decode the encoded data received from the flash memory using the low-density parity-check code and to provide the decoded data to the controller in response to one of the plurality of hard-decision decoders failing to decode the encoded data. The encoded data is obtained by the soft-decision decoder from the flash memory using a plurality of read-retry operations.

According to another aspect of the subject technology, a machine-implemented method is described herein. The method includes receiving encoded data from a flash memory at a hard-decision decoder in response to a read command and decoding the encoded data at the hard-decision decoder using a low-density parity-check code. If the hard-decision decoder decodes the encoded data, the decoded data is provided from the hard-decision decoder to the controller. If the hard-decision decoder fails to decode the encoded data, the encoded data is received from the flash memory at a soft-decision decoder, wherein the encoded data is obtained from the flash memory using a plurality of read-retry operations. The decoded data is decoded at the soft-decision decoder using the low-density parity-check code and provided from the soft-decision decoder to the controller.

According to another aspect of the subject technology, a machine-readable medium containing executable instructions which when executed cause the machine to perform a method is described herein. The method includes receiving encoded data from a flash memory at a hard-decision decoder in response to a read command and decoding the encoded data at the hard-decision decoder using a low-density parity-check code. If the hard-decision decoder decodes the encoded data, the decoded data is provided from the hard-decision decoder to the controller. If the hard-decision decoder fails to decode the encoded data, the encoded data is received from the flash memory at a soft-decision decoder, wherein the encoded data is obtained from the flash memory using a plurality of read-retry operations. The decoded data is decoded at the soft-decision decoder using the low-density parity-check code and provided from the soft-decision decoder to the controller.

According to another aspect of the subject technology, a solid state storage device is described herein. The solid state storage device includes a flash memory and a controller configured to store data in the flash memory via a plurality of channels, wherein the stored data is encoded using a low-density parity-check code. The solid state storage device further includes a plurality of decoders configured to decode encoded data received from the flash memory via respective channels of the plurality of channels in a first mode using the low-density parity-check code and to provide the decoded data to the controller in response to a read command from the controller. In response to one or more of the plurality of decoders failing to decode the encoded data in the first mode, the plurality of decoders are further configured to decode the encoded data in a second mode using the low-density parity-check code and to provide the decoded data to the controller in response to the read command from the controller. the encoded data is obtained from the flash memory in the second mode using a plurality of read-retry operations.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### BRIEF DESCRIPTION OF THE DRAWINGS

FIG. 1 is a block diagram depicting components of a solid state storage device according to one aspect of the subject technology.

FIG. 2 is a flowchart depicting a process for decoding LDPC encoded data according to one aspect of the subject technology.

FIG. 3 is a graph illustrating an example of programmed voltage distributions or programmed levels for a 2-bit MLC flash memory.

FIG. 4 is a graph illustrating an example of programmed voltage distributions for programmed levels for a 2-bit MLC flash memory after increasing the program verify levels for the middle two program levels.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be apparent to those skilled in the art that the subject technology may be practiced without some of these specific details. In some instances, well-known structures and components are shown in block diagram form in order to avoid obscuring the concepts of the subject technology.

Low-density parity-check (LDPC) codes can provide near optimal error correcting code (ECC) performance to overcome noise in data storage channels. LDPC decoders can use reliability (soft) information, such as log-likelihood ratios (LLRs), to correct bit errors that occur during storage and/or reading of stored data. In storage systems employing flash memory, such as solid state drives (SSDs), reliability information may be difficult to obtain since the detection process used to determine whether a read bit is a “1” or a “0” may be internal to the flash memory modules. For example, flash memory modules may simply output a binary decision of a “1” or a “0” to a decoder to perform error correction. These binary decisions may be referred to as “hard decisions.”

Reliability (soft) information may be obtained using a read retry process during which data is read from a flash memory module multiple times using different internal read settings for each read operation. The read settings may include read voltage levels, which are programmed into registers in the flash memory modules before each read iteration. This reliability (soft) information may be referred to as “soft decisions.” While decoding read data using soft decisions can be more effective than using hard decisions, the extra programming and read cycles required to obtain the reliability (soft) information may be too slow for high-performance SSD applications.

According to one aspect of the subject technology, the performance problems associated with obtaining soft information are at least partially circumvented by doing so only in cases when needed. Using a two-stage decoding scheme, the majority of read operations may be successfully completed using only the hard decisions obtained from the flash memory modules with a single read command. A hard-decision (HD) LDPC decoder is used for decoding during read operations using the hard decisions. Although a HD LDPC decoder may perform no better than a conventional BCH ECC decoder with comparable overhead (ECC parity bits), the same LDPC code can be used for a much more powerful soft-decision (SD) LDPC decoder when the HD LDPC decoder is unsuccessful.

As long as the usage of the SD LDPC decoder is limited to fraction of all user data read operations, the performance (IOPS, or user operations per second) will not be degraded significantly by the few read operations requiring soft LDPC decoding. Furthermore, the two-stage decoding scheme has the soft decoding to recover from a hard decoding failure and therefore does not require the hard decoding to be as reliable as conventional BCH ECC decoding must be. Flash memory error rates (before ECC decoding) typically increase as the flash memory is repeatedly erased and programmed through its life, until it reaches a point where the SSD reliability specifications would be compromised if further degradation occurs. The subject technology allows the SSD to continue using the flash memory far beyond the point where an SSD using a conventional BCH ECC would no longer be reliable. Therefore, the subject technology can provide an increase in the number of program/erase cycles of the flash memory before the SSD reliability goes out of spec.

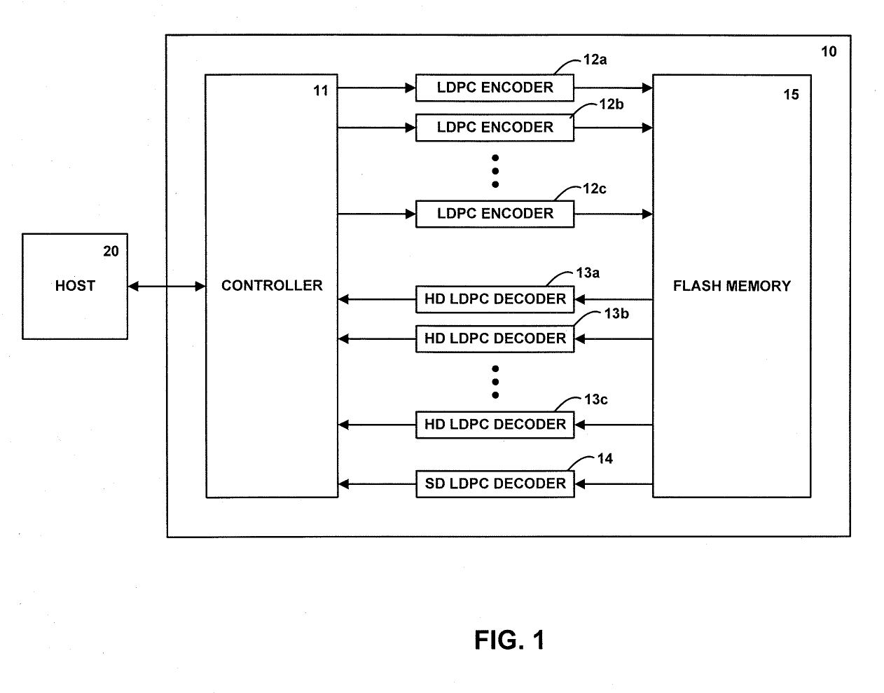

FIG. 1 is a block diagram depicting components of a solid state storage device 10 coupled in communication with a host 20. As depicted in FIG. 1, device 10 includes a controller 11, LDPC encoders 12a, 12b, 12c, HD LDPC decoders 13a, 13b, 13c, SD LDPC decoder 14, and flash memory 15. Briefly, controller 11 is configured to receive data from host 20 and store the data in flash memory 15 in response to a write request received from host 20. Prior to the data being stored in flash memory 15, LDPC encoders 12a, 12b, and 12c encode the data using an LDPC code. Controller 11 is further configured to read data stored in flash memory 15 in response to a read request received from host 20. The data read from flash memory, which was previously encoded using the LDPC code, is decoded by HD LDPC decoders 13a, 13b, 13c, and SD LDPC decoder 14 using in the LDPC code in a two-stage decoding process introduced above and discussed in more detail below. Controller 11 is configured to provide successfully decoded data to host 20 in response to the read request.

Controller 11 may be implemented with a general-purpose microprocessor, a microcontroller, a digital signal processor (DSP), an application specific integrated circuit (ASIC), a field programmable gate array (FPGA), a programmable logic device (PLD), a controller, a state machine, gated logic, discrete hardware components, or a combination of the foregoing. One or more sequences of instructions may be stored as firmware on ROM within controller 11 or external to controller 11. One or more sequences of instructions also may be stored and read from another storage medium, such as flash memory 15, or received from host 20 via a host interface. Device 10 also may include RAM either internal to controller 11 or external to controller 11 to provide temporary storage of data (e.g., buffer) and instructions and variables/settings that may be used by controller 11 to manage device 10 and perform the operations described herein. ROM, RAM, storage mediums, and flash memory represent examples of machine or computer readable media on which instructions/code executable by the controller may be stored. Machine or computer readable media may generally refer to any medium or media used to provide instructions to the controller, including both volatile media, such as dynamic memory used for storage media or for buffers within the controller, and non-volatile media, such as electronic media, optical media, and magnetic media.

Controller 11 may be coupled to and communicate with host 20 via a host interface. The host interface may be configured to implement a standard interface, such as Serial-Attached SCSI (SAS), Fiber Channel interface, PCI Express (PCIe), SATA, USB, and the like. The host interface may be configured to implement only one interface. Alternatively, the host interface may be configured to implement multiple interfaces, which are individually selectable using a configuration parameter selected by a user or programmed at the time of assembly. The host interface may include one or more buffers for buffering transmissions between host 20 and controller 11.

Host 20 represents a device configured to be coupled to solid state storage device 10 and to store data in solid state storage device 10 and read data from solid state storage device 10. Host 20 may be a computing system such as a personal computer, a server, a workstation, a laptop computer, PDA, smart phone, and the like. Alternatively, the host device may be an electronic device such as a digital camera, a digital audio player, a digital video recorder, and the like.

Flash memory 15 represents non-volatile memory devices for storing data. According to one aspect of the subject technology, flash memory 15 includes NAND flash memory. Flash memory 15 may be single-level cell (SLC) or multi-level cell (MLC) flash memory. Flash memory 15 may be configured using a single flash memory device or chip, or may include multiple flash memory devices or chips arranged in multiple channels. Flash memory 15 is not limited to any particular capacity or configuration. For example, the number of physical blocks, the number of physical pages per physical block, the number of sectors per physical page, and the size of the sectors may vary within the scope of the subject technology.

LDPC encoders 12a, 12b, and 12c represent encoding modules that are configured to encode data using an LDPC code. The data may be received directly from controller 11 or may be retrieved from a buffer external to controller 11. The LDPC code, codeword size, and code rate may be set based on trial and optimization data obtained through simulations and/or laboratory testing using the type and configuration of the flash memory used in device 10. According to one aspect, each of LDPC encoders 12a, 12b, and 12c is associated with a respective channel in device 10 for storing data in flash memory 15 in response to a write command from controller 11. Alternatively, LDPC encoders 12a, 12b, and 12c may be treated as pooled resources that can be allocated to channels for write operations as needed. The channel arrangement allows data read and write operations to be performed in parallel to improve throughput. While only three LDPC encoders are depicted in FIG. 1, corresponding to three channels, the subject technology may be implemented using any number of channels (e.g., eight, sixteen). LDPC encoders 12a, 12b, and 12c may be implemented using separate respective modules/chips or may be combined into one or more modules/chips with sufficient I/O ports to support the channels.

HD LDPC decoders 13a, 13b, and 13c represent decoding modules that are configured to decode encoded data read from flash memory 15 using hard decisions from flash memory 15 and the LDPC code used by LDPC encoders 12a, 12b, and 12c to encode the data. Similar to the LDPC encoders, HD LDPC decoders 13a, 13b, and 13c are each associated with a respective channel in device 10 for reading data from flash memory 15 in response to a read command from controller 11. As with the LDPC encoders, HD LDPC decoders 13a, 13b, and 13c may be treated as pooled resources that can be allocated to channels for read operations as needed. The channel arrangement allows data to be read from flash memory 15 in parallel to improve throughput in device 10. The parameters used for LDPC decoding (e.g., iteration count) performed by HD LDPC decoders 13a, 13b, and 13c may be set based on trial and optimization data obtained through simulations and/or laboratory testing using the type and configuration of the flash memory used in device 10. While only three HD LDPC decoders are depicted in FIG. 1, the subject technology may be implemented using any number of channels and the number of HD LDPC decoders will typically be equal to the number of LDPC encoders on an equal number of channels. HD LDPC decoders 13a, 13b, and 13c may be implemented using separate respective modules/chips or may be combined into one or more modules/chips with sufficient I/O ports to support the channels.

SD LDPC decoder 14 represents a decoding module that is configured to decode encoded data read from flash memory 15 that one or more of HD LDPC decoders 13a, 13b, and 13c was unable to decode. SD LDPC decoder 14 uses the same LDPC code that was used by the LDPC encoders prior to writing the data to flash memory 15 and by the HD LDPC decoders to try and decode the encoded data. SD LDPC decoder 14 is configured to decode the encoded data using soft decision information obtained from flash memory 15 using multiple read retry operations at different read settings programmed into flash memory 15. The soft decision parameters (e.g., read retry frequency, read voltage level settings) may be set based on trial and optimization data obtained through simulations and/or laboratory testing using the type and configuration of the flash memory used in device 10. SD LDPC decoder 14 may be configured to execute the soft decision process using multiple read retry operations at different read settings independent of controller 11 or in cooperation with controller 11 to program the registers in flash memory 11 with the read settings for each read retry.

While only one SD LDPC decoder is depicted in FIG. 1, the subject technology may be implemented with multiple SD LDPC decoders. For example, one SD LDPC decoder may be provided for each set of multiple channels (e.g., set of four channels, set of eight channels). This may further improve throughput in device 10 while still taking advantage of the leveraged two-staged decoding scheme described herein.

In an alternative arrangement, HD LDPC decoders 13a, 13b, and 13c may be implemented using multi-mode LDPC decoders that are configurable to operate in either a hard decoding mode or a soft decoding mode. In this arrangement, the multi-mode LDPC decoders may be operated in a hard decoding mode in the same manner as the HD LDPC decoders described herein during read operations and in a soft decoding mode in the same manner as the SD LDPC decoders described herein in the event a hard decoding operation was unsuccessful. Controller 11 may be configured to set the operating mode of the multi-mode LDPC decoders as needed or the multi-mode LDPC decoders may be configured to automatically switch from the hard decoding mode to the soft decoding mode when a hard decoding operation fails in the decoder. Similar to the arrangements described above, the multi-mode LDPC decoders may be treated as pooled resources and allocated to channels as needed for read operations.

FIG. 1 depicts LDPC encoders 12a, 12b, 12c, HD LDPC decoders 13a, 13b, 13c, and SD LDPC decoder 14 as components separate from controller 11. The subject technology may be implemented with one or more of LDPC encoders 12a, 12b, 12c, HD LDPC decoders 13a, 13b, 13c, and SD LDPC decoder 14 integrated within controller 11.

The two-stage scheme of the subject technology relies on HD LDPC decoders to do the majority of the work, with a SD LDPC decoder being available when needed to recover from hard decoding failures. Upon invoking the soft decoder, a sequence of read operations is performed on the flash memory page where the data resides to obtain a soft decision. The SD LDPC decoder then decodes the encoded data using the soft decision and the LDPC code. The multiple read retry operations may be done at different read voltage levels to allow the individual bits of data read from flash memory 15 to be categorized by reliability information.

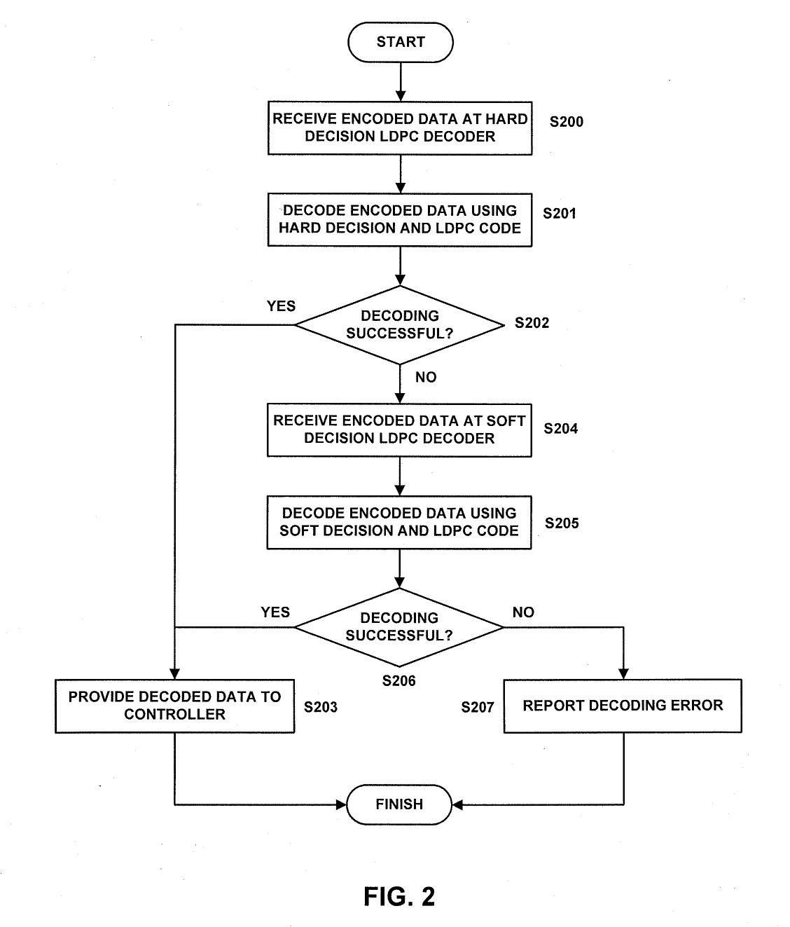

FIG. 2 is a flowchart depicting a two-stage LDPC decoding process according to one aspect of the subject technology. The process may be initiated by controller 11 issuing a read command to flash memory 15. The read command may be in response to a read request received from host 20. Alternatively, the read command may be in response to a housekeeping process, such as garbage collection, executed by controller 11. The process may be performed by controller 11 and/or one of the LDPC decoders executing one or more sequences of instructions stored in a computer or machine-readable medium in device 10.

In step S200, encoded data (e.g., codeword with possible data errors) is read from flash memory based on the read command and is received by one of the HD LDPC decoders. The encoded data is provided as hard decision data to the HD LDPC decoder, which decodes the encoded data in step 5201 using the LDPC code used to encode the data. As noted above, the parameters for performing LDPC decoding may be optimized and set in device 10 based on simulations and/or laboratory testing.

In step S202, the process determines if the HD LDPC decoder was able to decode the encoded data received from the flash memory. If the decoding was successfully completed, the decoded data is provided to the controller, or a buffer accessible by the controller, in step 5203. The controller may then either provide the decoded data to the requesting host in response to previous read command or perform housekeeping operations on the decoded data.

If in step 5202 the process determines that the HD LDPC decoder was unsuccessful at decoding the encoded data, the encoded data is obtained and received by the SD LDPC decoder in the form of soft decision data in step S204. As noted above, the soft decision data is obtained from the flash memory through a sequence of read retries each performed at different read settings (e.g., read level voltages). The read retries may be set and requested by the controller and/or the SD LDPC decoder. In step S205, the SD LDPC decoder decodes the encoded data using the soft information and the LDPC code used to encode the data.

In step S206, the process determines if the SD LDPC decoder was successful at decoding the encoded data. If the encoded was successfully decoded by the SD LDPC decoder, the process goes to step 5203 where the decoded data is provided to the controller, or a buffer accessible by the controller. If the SD LDPC decoder was not successful at decoding the encoded data, a failure or read error is reported to the controller, which may subsequently report the read error to the requesting host. After either providing the decoded data to the controller or reporting a decoding or read error, the process ends until the next read command is issued from controller 11.

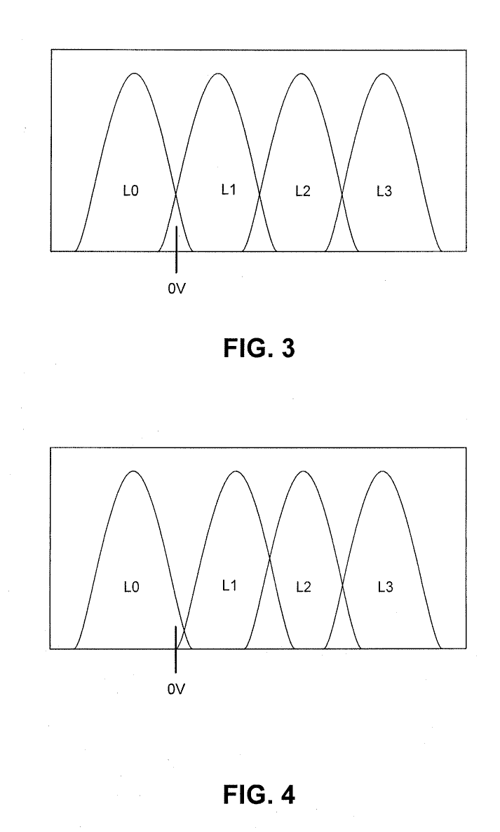

FIG. 3 is a graph illustrating an example of programmed voltage distributions or programmed levels for a 2-bit MLC flash memory. As depicted in FIG. 3, the graph includes distributions for unprogrammed level L0, first programmed level L1, second programmed level L2, and third programmed level L3. The performance of the LDPC decoding may be improved by moving one or more of the programmed voltage distributions up. Programmed voltage distributions may be moved up by increasing the corresponding program verify levels, for example. Over time, flash memory loses charge which causes the threshold voltage of cells to drop. The more program/erase cycles the flash memory has experienced, the more extreme the decline in charge and threshold voltage will be. As all of the threshold voltage values drop in a MLC flash memory, some of the cells programmed to the first programmed level may fall below 0V. These cells may be detected/read as unprogrammed since many flash memory devices do not allow a read level to be placed below 0V. Eventually, these errors may dominate the overall error rate in the flash memory.

In MLC flash memory, voltage level distributions also tend to shift to lower voltages, as mentioned above, and widen over time. In 2-bit MLC, this shifting and/or widening typically occurs with levels L1, L2, and L3, while L0 remains relatively steady. As the distributions widen and shift, the distributions may drop below read voltage levels. For example, L1 cells may drop below 0V causing a read error identifying the L1 cell as an L0 cell. By shifting the voltage level distribution for L1 up with a increased program verify voltage level, these errors may be reduced.

The subject technology may improve the performance of the LDPC decoding by moving the programmed voltage distributions up by increasing the corresponding program verify voltage levels. In this manner, programmed cells are able to lose more charge and reduce their associated threshold voltage levels further before they drop below 0V into negative territory. According to one aspect, the program verify voltage level for L1 may be increased by 250 mV and the program verify voltage level for L2 may be increased by 125 mV. The subject technology is not limited to these values, which may vary depending on the voltage level distributions for the flash memory. For example, the program verify levels for L1 and L2 may be varied to better balance the read errors between L0 and L1, between L1 and L2, and between L2 and L3 so that the performance of the flash memory is not dominated by errors between L0 and L1.

FIG. 4 is a graph illustrating an example of the resulting voltage level distributions due to increasing the program verify levels for L1 and L2. The resulting shifts in voltage distributions may result in an increase in bit errors when reading the least-significant bit (LSB) page from an MLC flash memory together with a possible decrease in bit errors when reading the most-significant bit (MSB) page from the MLC flash memory. These changes are expected given the reduced likelihood that cells in L1 may shift below 0V and the increase in overlap between L1 and L2 and between L2 and L3. Providing a better balance between the read errors at these different levels may help improve the LDPC decoding by making the soft LDPC decoding more effective thereby improving the overall reliability of the flash memory. Simulations and/or test data may be obtained and used to determine how much the program verify levels should be shifted to improve the performance of the LDPC decoding.

The adjustments to the program verify voltage levels may be consistent through the life of the device or may vary as the device ages. Error rates and/or program/erase cycles may be monitored and used to adjust the program verify voltage levels. The different program verify voltage levels may be stored in a look-up table or may be calculated using an algorithm based on error rates and/or program/erase cycles of the flash memory. The different program verify voltage levels may be determined based on simulations or actual tests on flash memory devices.

The various illustrative blocks, modules, elements, components, methods, and algorithms described herein may be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

It is understood that the specific order or hierarchy of steps in the processes disclosed is an illustration of exemplary approaches. Based upon design preferences, it is understood that the specific order or hierarchy of steps in the processes may be rearranged. Some of the steps may be performed simultaneously. The accompanying method claims present elements of the various steps in a sample order, and are not meant to be limited to the specific order or hierarchy presented.

A phrase such as an “aspect” does not imply that such aspect is essential to the subject technology or that such aspect applies to all configurations of the subject technology. A disclosure relating to an aspect may apply to all configurations, or one or more configurations. An aspect may provide one or more examples. A phrase such as an “aspect” may refer to one or more aspects and vice versa. A phrase such as an “embodiment” does not imply that such embodiment is essential to the subject technology or that such embodiment applies to all configurations of the subject technology. A disclosure relating to an embodiment may apply to all embodiments, or one or more embodiments. An embodiment may provide one or more examples. A phrase such as an “embodiment” may refer to one or more embodiments and vice versa. A phrase such as a “configuration” does not imply that such configuration is essential to the subject technology or that such configuration applies to all configurations of the subject technology. A disclosure relating to a configuration may apply to all configurations, or one or more configurations. A configuration may provide one or more examples. A phrase such as a “configuration” may refer to one or more configurations and vice versa.

What is claimed is:

1. A solid state storage device, comprising:
a flash memory;
a controller configured to store data in the flash memory via a plurality of channels, wherein the stored data is encoded using a low-density parity-check code;
a plurality of hard-decision decoders configured to decode encoded data received from the flash memory via respective channels of the plurality of channels using the low-density parity-check code and to provide decoded data to the controller in response to one or more read commands from the controller; and
a soft-decision decoder configured to decode the encoded data received from the flash memory using the low-density parity-check code and to provide the decoded data to the controller in response to one of the plurality of hard-decision decoders failing to decode the encoded data, wherein the soft-decision decoder is configured to obtain the encoded data from the flash memory using a plurality of read-retry operations.

2. The solid state storage device according to claim 1, further comprising a plurality of encoders configured to encode the stored data using the low-density parity-check code via respective channels of the plurality of channels.

3. The solid state storage device according to claim 1, wherein the flash memory is a multi-level cell flash memory.

4. The solid state storage device according to claim 3, wherein the controller is further configured to program write settings in the multi-level cell flash memory for write operations in the multi-level cell flash memory.

5. The solid state storage device according to claim 4, wherein the write settings comprise program verify voltage levels.

6. The solid state storage device according to claim 5, wherein each cell in the multi-level cell flash memory is configured to be set at one of an unprogrammed level, a first programmed level, a second programmed level, and a third programmed level, and
wherein the controller is configured to increase the program verify voltage levels for the first programmed level and the second programmed level in the multi-level cell flash memory.

7. The solid state storage device according to claim 6, wherein the controller is configured to increase the program verify voltage levels based on a program-erase cycle count of the multi-level cell flash memory.

8. The solid state storage device according to claim 5, wherein the controller is configured to program the program verify voltage levels in the multi-level cell flash memory to increase an error rate associated with reading a least-significant bit page and decrease an error rate associated with reading a most-significant bit page.

9. The solid state storage device according to claim 1, wherein the flash memory comprises a plurality of flash memory modules, the plurality of flash memory modules corresponding to respective ones of the plurality of channels.

10. A machine-implemented method comprising:
receiving encoded data from a flash memory at a hard-decision decoder in response to a read command;
decoding the encoded data at the hard-decision decoder using a low-density parity-check code;
if the hard-decision decoder decodes the encoded data, providing the decoded data from the hard-decision decoder to the controller;
if the hard-decision decoder fails to decode the encoded data, receiving the encoded data from the flash memory at a soft-decision decoder, wherein the soft-decision decoder obtains the encoded data from the flash memory using a plurality of read-retry operations;
decoding the decoded data at the soft-decision decoder using the low-density parity-check code; and
providing the decoded data from the soft-decision decoder to the controller.

11. The method according to claim 10, wherein the flash memory is a multi-level cell flash memory, the method further comprising:
programming write settings in the multi-level cell flash memory.

12. The method according to claim 11, further comprising:
encoding data received from the controller at an encoder using the low-density parity-check code; and
writing the data encoded by the encoder to the flash memory using the programmed write settings.

13. The method according to claim 11, wherein the write settings comprise program verify voltage levels.

14. The method according to claim 13, wherein each cell in the multi-level cell flash memory is configured to be set at one of an unprogrammed level, a first programmed level, a second programmed level, and a third programmed level, and
wherein programming the write settings comprises:
increasing a program verify voltage level for the first programmed level; and
increasing a program verify voltage level for the second programmed level.

15. The method according to claim 14, wherein the write settings are programmed based on a program-erase cycle count of the multi-level cell flash memory.

16. The method according to claim 13, wherein the program verify voltage levels are programmed to increase an error rate associated with reading a least-significant bit page and to decrease an error rate associated with reading a most-significant bit page.

17. A machine-readable medium containing executable instructions which when executed cause the machine to perform a method comprising:
receiving encoded data from a flash memory at a hard-decision decoder in response to a read command;
decoding the encoded data at the hard-decision decoder using a low-density parity-check code;
if the hard-decision decoder decodes the encoded data, providing the decoded data from the hard-decision decoder to the controller;
if the hard-decision decoder fails to decode the encoded data, receiving the encoded data from the flash memory at a soft-decision decoder, wherein the encoded data is obtained by the soft-decision decoder using a plurality of read-retry operations;
decoding the decoded data at the soft-decision decoder using the low-density parity-check code; and
providing the decoded data from the soft-decision decoder to the controller.

18. The machine-readable medium according to claim 17, wherein the flash memory is a multi-level cell flash memory, the method further comprising:
programming write settings in the multi-level cell flash memory.

19. The machine-readable medium according to claim 18, the method further comprising:
encoding data received from the controller at an encoder using the low-density parity-check code; and
writing the data encoded by the encoder to the flash memory using the programmed write settings.

20. The machine-readable medium according to claim 18, wherein the write settings comprise program verify voltage levels.

21. The machine-readable medium according to claim 20, wherein each cell in the multi-level cell flash memory is configured to be set at one of an unprogrammed level, a first programmed level, a second programmed level, and a third programmed level, and
wherein programming the write settings comprises:
increasing a program verify voltage level for the first programmed level; and
increasing a program verify voltage level for the second programmed level.

22. The machine-readable medium according to claim 20, wherein the write settings are programmed based on a program-erase cycle count of the multi-level cell flash memory.

23. The machine-readable medium according to claim 20, wherein the program verify voltage levels are programmed to increase an error rate associated with reading a least-significant bit page and to decrease an error rate associated with reading a most-significant bit page.

24. A solid state storage device, comprising:
a flash memory;
a controller configured to store data in the flash memory via a plurality of channels, wherein the stored data is encoded using a low-density parity-check code; and
a plurality of decoders configured to decode encoded data received from the flash memory via respective channels of the plurality of channels in a first mode using the low-density parity-check code and to provide the decoded data to the controller in response to a read command from the controller,
wherein, in response to one or more of the plurality of decoders failing to decode the encoded data in the first mode, the plurality of decoders are further configured to decode the encoded data in a second mode using the low-density parity-check code and to provide the decoded data to the controller in response to the read command from the controller,
wherein the encoded data is obtained from the flash memory in the second mode using a plurality of read-retry operations.

25. The solid state storage device according to claim 24, further comprising a plurality of encoders configured to encode the stored data using the low-density parity-check code via respective channels of the plurality of channels.

26. The solid state storage device according to claim 24, wherein the flash memory is a multi-level cell flash memory.

27. The solid state storage device according to claim 26, wherein the controller is further configured to program write settings in the multi-level cell flash memory for write operations in the multi-level cell flash memory.

28. The solid state storage device according to claim 27, wherein the write settings comprise program verify voltage levels.

29. The solid state storage device according to claim 28, wherein each cell in the multi-level cell flash memory is configured to be set at one of an unprogrammed level, a first programmed level, a second programmed level, and a third programmed level, and wherein the controller is configured to increase the program verify voltage levels for the first programmed level and the second programmed level in the multi-level cell flash memory.

30. The solid state storage device according to claim 27, wherein the controller is configured to increase the program verify voltage levels based on a program-erase cycle count of the multi-level cell flash memory.

31. The solid state storage device according to claim 28, wherein the controller is configured to program the program verify voltage levels in the multi-level cell flash memory to increase an error rate associated with reading a least-significant bit page and decrease an error rate associated with reading a most-significant bit page.

32. The solid state storage device according to claim 24, wherein the flash memory comprises a plurality of flash memory modules, the plurality of flash memory modules corresponding to respective ones of the plurality of channels.
